(19) United States
(12) Patent Application Publication
(10) Pub. No.: US 2019/0250859 A1
(43) Pub. Date: Aug. 15, 2019

(54) EMBEDDED ARCHITECTURE USING INTER-PROCESSOR COMMUNICATION AND IN MEMORY DATABASE FOR RAPID CREATION OF INDUSTRIAL PROTOCOL CONVERTERS

(71) Applicant: Plex Systems, Inc., Troy, MI (US)

(72) Inventor: Shaun Greene, Indianapolis, IN (US)

(21) Appl. No.: 16/271,223

(22) Filed: Feb. 8, 2019

Related U.S. Application Data
(60) Provisional application No. 62/628,525, filed on Feb. 9, 2018.

(51) Int. Cl. G06F 3/06; H04L 29/08; G06F 16/23; G06F 16/18; G11C 11/00

(52) U.S. Cl. CPC G06F 3/0685; H04L 67/26; G06F 16/2379; H04L 67/12; G11C 11/00; G06F 3/0638; G06F 3/0611; G06F 3/0619; G06F 3/065; G06F 16/1805

(57) ABSTRACT

Systems and methods for managing data at a gateway device receiving sensor data is discussed. An in-memory persistent database can provide a common application programming interface (API) for pushing data from one or more drivers that receive sensor data over various communication protocols. The common API can also be utilized by a data sender application to pull data from the in-memory persistent database and send the pulled data to a remote server such as a cloud storage. The in-memory persistent database stores the sensor data in time ordered pipeline data structures. A configuration data structure is maintained for each set of sensors and can be accessed and modified using the common API.

### CROSS-REFERENCE TO RELATED APPLICATIONS

The present Application for Patent claims priority to U.S. Provisional Application No. 62/628,525 entitled “EMBEDDED ARCHITECTURE USING INTER-PROCESSOR COMMUNICATION AND IN MEMORY DATABASE FOR RAPID CREATION OF INDUSTRIAL PROTOCOL CONVERTERS,” filed Feb. 9, 2018, which is incorporated herein in its entirety.

### FIELD OF THE DISCLOSURE

The present disclosure is generally directed to networking. In particular, the present disclosure describes techniques for data communication.

### BACKGROUND OF THE DISCLOSURE

An Internet-of-Things (IoT) platform can receive data from several devices or systems over a network. The IoT platform can store, process, or transmit the received data. In some instances, devices may push data over the Internet to one or more cloud servers.

### BRIEF SUMMARY OF THE DISCLOSURE

In certain embodiments, a method for managing data at a gateway device receiving sensor data can include receiving, at a plurality of drivers, sensor data, each of the plurality of drivers receiving sensor data over a different communication protocol. The method further includes providing, by an in-memory persistent database, a common API to the plurality of drivers. The method also includes receiving, by the in-memory persistent database, via the common API, a data store request from at least one driver from the plurality of drivers, the data store request including a first API key unique to a first set of sensors. The method additionally includes storing, by the in-memory persistent database, data received from the at least one driver in at least one data pipeline data structure, the at least one data pipeline data structure indexed by the first API key. The method also includes receiving, by the in-memory persistent database from a data sender application via the common API, a data pull request including the first API key. The method further includes providing, by the in-memory persistent database, data stored in the data pipeline data structure indexed by the first API key to the data sender application. The method additionally includes transmitting, by the data sender application to a remote server, the data stored in the data pipeline structure provided by the in-memory persistent database.

In some embodiments, the at least one data pipeline data structure includes a data pipeline, and where storing, by the in-memory persistent database, data received from the at least one driver in the at least one data pipeline data structure includes storing sensor data received from the at least one driver in the data pipeline. In some embodiments, the at least one data pipeline data structure includes an events pipeline, and where storing, by the in-memory persistent database, data received from the at least one driver in the at least one data pipeline data structure includes storing sensor events data received from the at least one driver in the events pipeline. In some embodiments, the at least one data pipeline data structure includes a conditions pipeline, and where storing, by the in-memory persistent database, data received from the at least one driver in the at least one data pipeline data structure includes storing sensor conditions data received from the at least one driver in the conditions pipeline.

In some embodiments, storing, by the in-memory persistent database, data in the at least one data pipeline data structure includes storing data in a sorted set based on time stamps associated with the data. In some embodiments, the method further includes storing on demand, by the in-memory persistent database, data in the at least one data pipeline data structure in a non-volatile disc. In some embodiments, the method also includes receiving, by the in-memory persistent database, an application layer store request to store configuration data, the request including a second API key unique to the first set of sensors and configuration data, and storing, by the in-memory persistent database, the configuration data in a configuration data structure indexed by the second API key. In some embodiments, the configuration data is in JSON format, and wherein storing the configuration data in a configuration data structure includes storing the configuration data in the received JSON format. In some embodiments, the method also includes receiving, by the in-memory persistent database, an application layer read request to read configuration data stored in the configuration data structure, the read request including the second API key, and transmitting, by the in-memory persistent database, the configuration data stored in the configuration data structure indexed by the second API key. In some embodiments, the method further includes updating, by the in-memory persistent database, the configuration data with data from the at least one data pipeline data structure indexed by the first API key.

In some embodiments, a system managing data at a gateway device receiving sensor data, includes a plurality of drivers executing on one or more servers, each of the plurality of drivers configured to receive sensor data over a different communication protocol. The system further includes an in-memory persistent database executing on one or more servers, wherein the in-memory persistent database is configured to provide a common API to the plurality of drivers. The in-memory persistent database is further configured to receive via the common API a data store request from at least one driver from the plurality of drivers, the data request including a first API key unique to a first set of sensors. The in-memory persistent database is also configured to store data received from the at least one driver in at least one data pipeline data structure, the at least one data pipeline data structure indexed by the first API key. The in-memory persistent database is further configured to receive from a data sender application via the common API, a data pull request including the first API key. The in-memory persistent database is also configured to provide data stored in the data pipeline data structure indexed by the first API key to the data sender application. The system further includes a data sender application running on the one or more servers, the data sender application configured to transmit to a remote server the data stored in the data pipeline structure provided by the in-memory persistent database.

In some embodiments, the at least one data pipeline data structure includes a data pipeline, and where the in-memory persistent database is configured to store sensor data received from the at least one driver in the data pipeline. In some embodiments, the at least one data pipeline data structure includes an events pipeline, and where the in-memory persistent database is configured to store sensor events data received from the at least one driver in the events pipeline. In some embodiments, the at least one data pipeline data structure includes a conditions pipeline, and where the in-memory persistent database is configured to store sensor conditions data received from the at least one driver in the conditions pipeline.

In some embodiments, the in-memory persistent database is configured to store data in the at least one data pipeline data structure in a sorted set based on time stamps associated with the data. In some embodiments, the in-memory persistent database is configured to store on demand data in the at least one data pipeline data structure in a non-volatile disc. In some embodiments, the in-memory persistent database is configured to receive an application layer store request to store configuration data, the request including a second API key unique to the first set of sensors and configuration data, and store the configuration data in a configuration data structure indexed by the second API key. In some embodiments, the configuration data is in JSON format, and wherein the in-memory persistent database is configured to store the configuration data in the received JSON format. In some embodiments, the in-memory persistent database is configured to receive an application layer read request to read configuration data stored in the configuration data structure, the read request including the second API key, and transmit the configuration data stored in the configuration data structure indexed by the second API key. In some embodiments, the in-memory persistent database is configured to update the configuration data with data from the at least one data pipeline data structure indexed by the first API key.

### BRIEF DESCRIPTION OF THE DRAWINGS

The foregoing and other objects, aspects, features, and advantages of the disclosure will become more apparent and better understood by referring to the following description taken in conjunction with the accompanying drawings, in which:

FIG. 1A is a block diagram depicting an embodiment of a network environment comprising a client device in communication with server device;

FIG. 1B is a block diagram depicting a cloud computing environment comprising client device in communication with cloud service providers;

FIGS. 1C and 1D are block diagrams depicting embodiments of computing devices useful in connection with the methods and systems described herein;

FIG. 2 shows a block diagram of an example micro-service architecture for embedded gateways;

FIG. 3 shows a screenshot of an example process for obtaining the configuration data from the in-memory persistent database;

FIG. 4 shows a block diagram representation of an example in-memory persistent database of the embedded gateway; and

FIG. 5 shows an example inter-processor communication diagram.

### DETAILED DESCRIPTION

For purposes of reading the description of the various embodiments below, the following descriptions of the sections of the specification and their respective contents may be helpful:

Section A describes a network environment and computing environment which may be useful for practicing embodiments described herein.

Section B describes embodiments of systems and methods for industrial protocol converters.

A. Computing and Network Environment

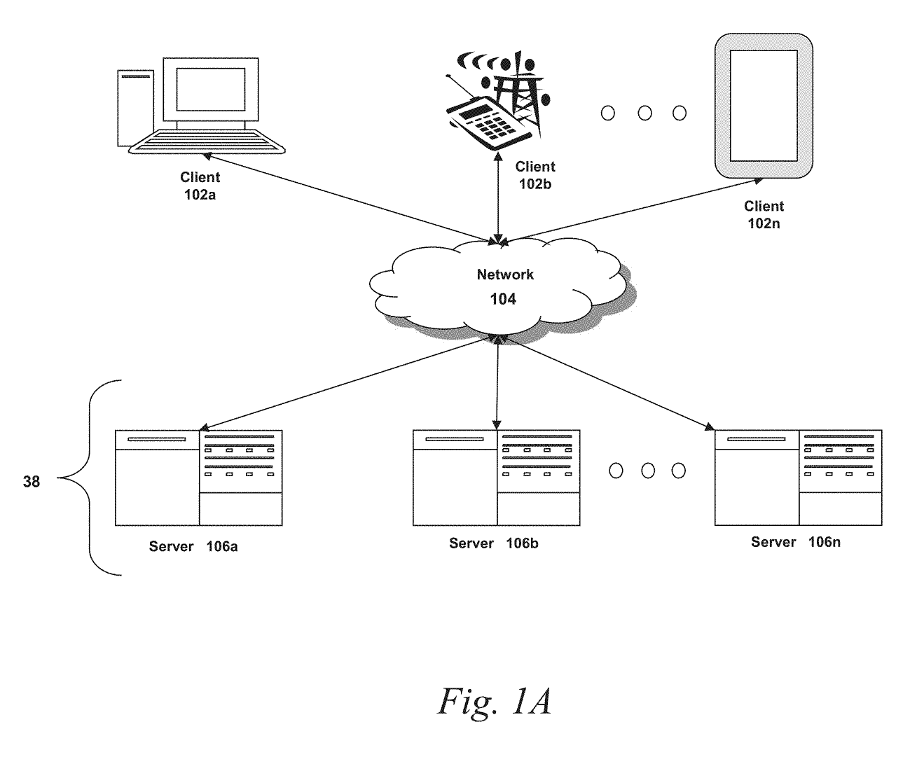

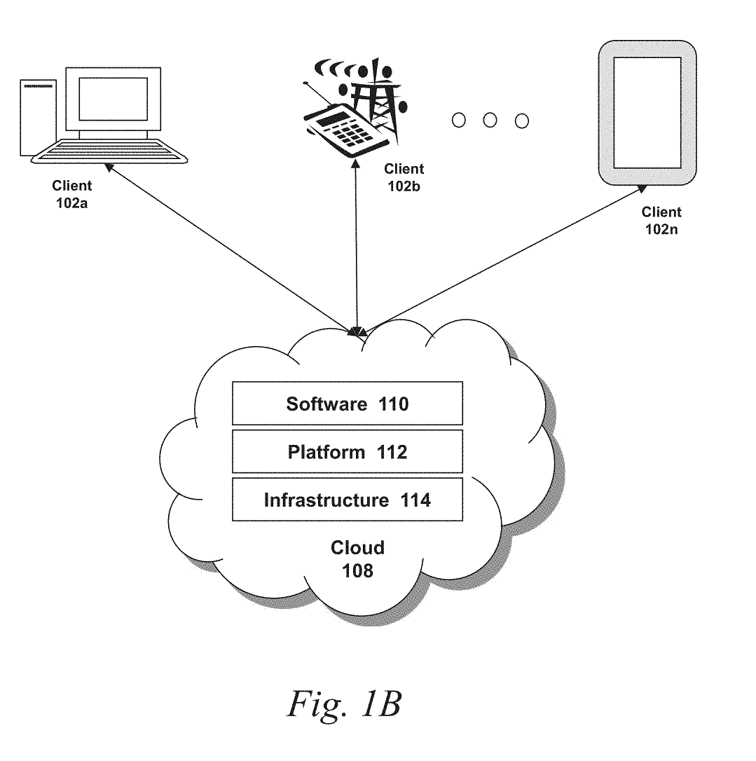

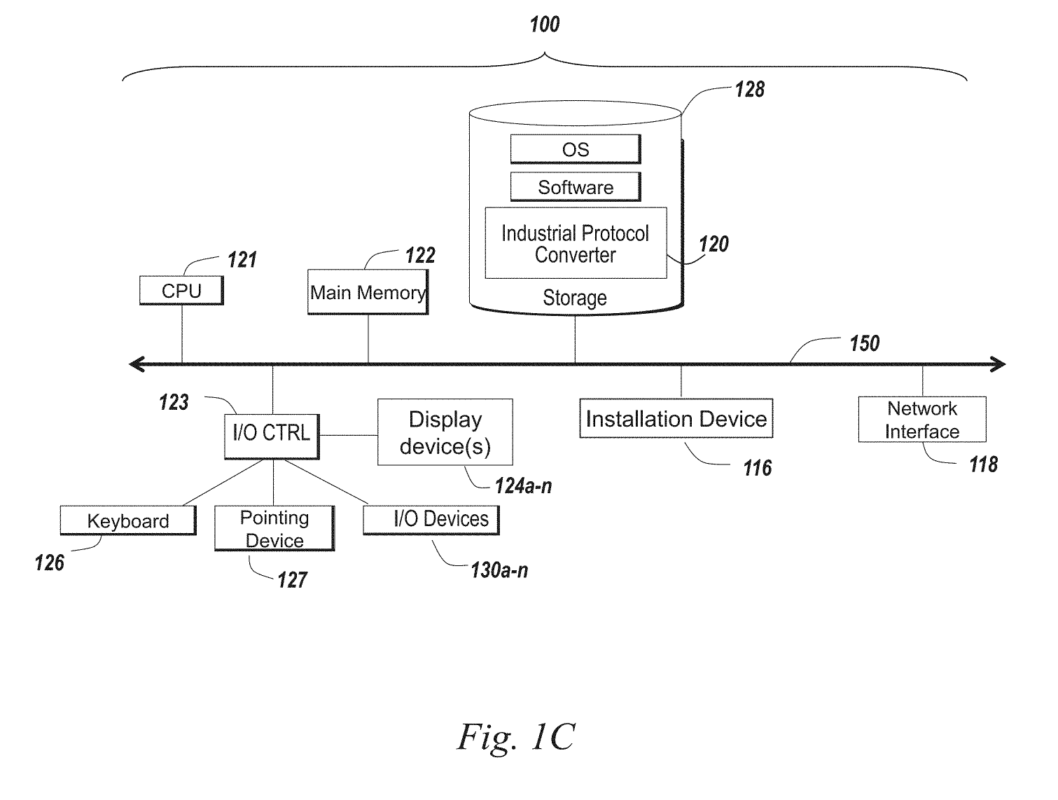

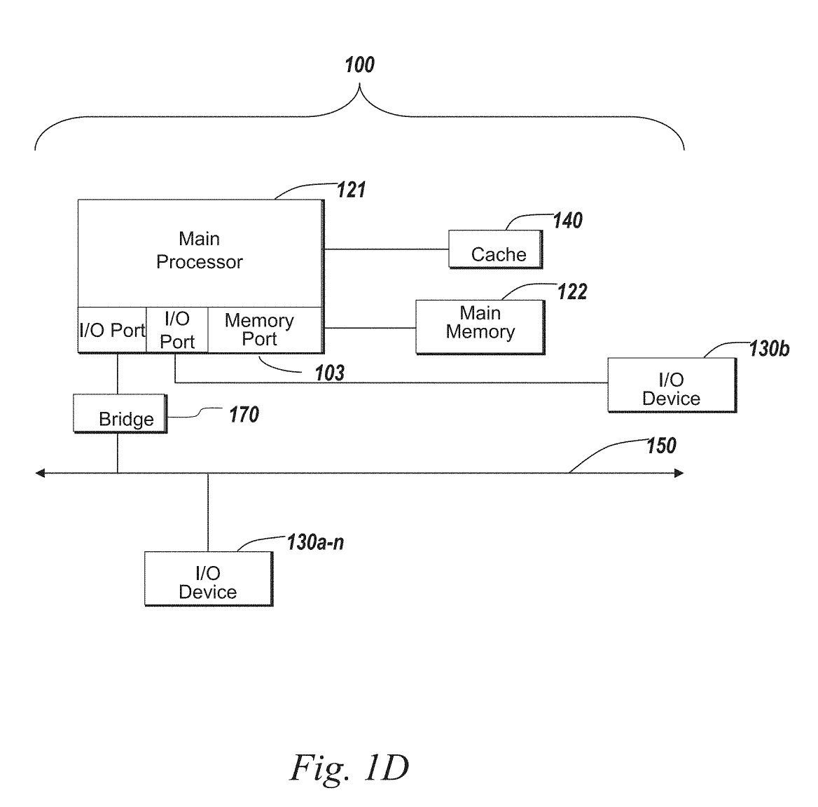

Prior to discussing specific embodiments of the present solution, it may be helpful to describe aspects of the operating environment as well as associated system components (e.g., hardware elements) in connection with the methods and systems described herein. Referring to FIG. 1A, an embodiment of a network environment is depicted. In brief overview, the network environment includes one or more clients 102a-102n (also generally referred to as local machine(s) 102, client(s) 102, client node(s) 102, client machine(s) 102, client computer(s) 102, client device(s) 102, endpoint(s) 102, or endpoint node(s) 102) in communication with one or more servers 106a-106n (also generally referred to as server(s) 106, node 106, or remote machine(s) 106) via one or more networks 104. In some embodiments, a client 102 has the capacity to function as both a client node seeking access to resources provided by a server and as a server providing access to hosted resources for other clients 102a-102n.

Although FIG. 1A shows a network 104 between the clients 102 and the servers 106, the clients 102 and the servers 106 may be on the same network 104. In some embodiments, there are multiple networks 104 between the clients 102 and the servers 106. In one of these embodiments, a network 104′ (not shown) may be a private network and a network 104 may be a public network. In another of these embodiments, a network 104 may be a private network and a network 104′ a public network. In still another of these embodiments, networks 104 and 104′ may both be private networks.

The network 104 may be connected via wired or wireless links. Wired links may include Digital Subscriber Line (DSL), coaxial cable lines, or optical fiber lines. The wireless links may include BLUETOOTH, Wi-Fi, Worldwide Interoperability for Microwave Access (WiMAX), an infrared channel or satellite band. The wireless links may also include any cellular network standards used to communicate among mobile devices, including standards that qualify as 1G, 2G, 3G, or 4G. The network standards may qualify as one or more generation of mobile telecommunication standards by fulfilling a specification or standards such as the specifications maintained by International Telecommunication Union. The 3G standards, for example, may correspond to the International Mobile Telecommunications-2000 (IMT-2000) specification, and the 4G standards may correspond to the International Mobile Telecommunications Advanced (IMT-Advanced) specification. Examples of cellular network standards include AMPS, GSM, GPRS, UMTS, LTE, LTE Advanced, Mobile WiMAX, and WiMAX-Advanced. Cellular network standards may use various channel access methods e.g. FDMA, TDMA, CDMA, or SDMA. In some embodiments, different types of data may be transmitted via different links and standards. In other embodiments, the same types of data may be transmitted via different links and standards.

The network 104 may be any type and/or form of network. The geographical scope of the network 104 may vary widely and the network 104 can be a body area network (BAN), a personal area network (PAN), a local-area network (LAN), e.g. Intranet, a metropolitan area network (MAN), a wide area network (WAN), or the Internet. The topology of the network 104 may be of any form and may include, e.g., any of the following: point-to-point, bus, star, ring, mesh, or tree. The network 104 may be an overlay network which is virtual and sits on top of one or more layers of other networks 104′. The network 104 may be of any such network topology as known to those ordinarily skilled in the art capable of supporting the operations described herein. The network 104 may utilize different techniques and layers or stacks of protocols, including, e.g., the Ethernet protocol, the internet protocol suite (TCP/IP), the ATM (Asynchronous Transfer Mode) technique, the SONET (Synchronous Optical Networking) protocol, or the SDH (Synchronous Digital Hierarchy) protocol. The TCP/IP internet protocol suite may include application layer, transport layer, internet layer (including, e.g., IPv6), or the link layer. The network 104 may be a type of a broadcast network, a telecommunications network, a data communication network, or a computer network.

In some embodiments, the system may include multiple, logically-grouped servers 106. In one of these embodiments, the logical group of servers may be referred to as a server farm 38 or a machine farm 38. In another of these embodiments, the servers 106 may be geographically dispersed. In other embodiments, a machine farm 38 may be administered as a single entity. In still other embodiments, the machine farm 38 includes a plurality of machine farms 38. The servers 106 within each machine farm 38 can be heterogeneous—one or more of the servers 106 or machines 106 can operate according to one type of operating system platform (e.g., WINDOWS NT, manufactured by Microsoft Corp. of Redmond, Wash.), while one or more of the other servers 106 can operate on according to another type of operating system platform (e.g., Unix, Linux, or Mac OS X).

In one embodiment, servers 106 in the machine farm 38 may be stored in high-density rack systems, along with associated storage systems, and located in an enterprise data center. In this embodiment, consolidating the servers 106 in this way may improve system manageability, data security, the physical security of the system, and system performance by locating servers 106 and high performance storage systems on localized high performance networks. Centralizing the servers 106 and storage systems and coupling them with advanced system management tools allows more efficient use of server resources.

The servers 106 of each machine farm 38 do not need to be physically proximate to another server 106 in the same machine farm 38. Thus, the group of servers 106 logically grouped as a machine farm 38 may be interconnected using a wide-area network (WAN) connection or a metropolitan-area network (MAN) connection. For example, a machine farm 38 may include servers 106 physically located in different continents or different regions of a continent, country, state, city, campus, or room. Data transmission speeds between servers 106 in the machine farm 38 can be increased if the servers 106 are connected using a local-area network (LAN) connection or some form of direct connection. Additionally, a heterogeneous machine farm 38 may include one or more servers 106 operating according to a type of operating system, while one or more other servers 106 execute one or more types of hypervisors rather than operating systems. In these embodiments, hypervisors may be used to emulate virtual hardware, partition physical hardware, virtualize physical hardware, and execute virtual machines that provide access to computing environments, allowing multiple operating systems to run concurrently on a host computer. Native hypervisors may run directly on the host computer. Hypervisors may include VMware ESX/ESXi, manufactured by VMWare, Inc., of Palo Alto, Calif.; the Xen hypervisor, an open source product whose development is overseen by Citrix Systems, Inc.; the HYPER-V hypervisors provided by Microsoft or others. Hosted hypervisors may run within an operating system on a second software level. Examples of hosted hypervisors may include VMware Workstation and VIRTUALB OX.

Management of the machine farm 38 may be de-centralized. For example, one or more servers 106 may comprise components, subsystems and modules to support one or more management services for the machine farm 38. In one of these embodiments, one or more servers 106 provide functionality for management of dynamic data, including techniques for handling failover, data replication, and increasing the robustness of the machine farm 38. Each server 106 may communicate with a persistent store and, in some embodiments, with a dynamic store.

Server 106 may be a file server, application server, web server, proxy server, appliance, network appliance, gateway, gateway server, virtualization server, deployment server, SSL VPN server, or firewall. In one embodiment, the server 106 may be referred to as a remote machine or a node. In another embodiment, a plurality of nodes 290 may be in the path between any two communicating servers.

Referring to FIG. 1B, a cloud computing environment is depicted. A cloud computing environment may provide client 102 with one or more resources provided by a network environment. The cloud computing environment may include one or more clients 102a-102n, in communication with the cloud 108 over one or more networks 104. Clients 102 may include, e.g., thick clients, thin clients, and zero clients. A thick client may provide at least some functionality even when disconnected from the cloud 108 or servers 106. A thin client or a zero client may depend on the connection to the cloud 108 or server 106 to provide functionality. A zero client may depend on the cloud 108 or other networks 104 or servers 106 to retrieve operating system data for the client device. The cloud 108 may include back end platforms, e.g., servers 106, storage, server farms or data centers.

The cloud 108 may be public, private, or hybrid. Public clouds may include public servers 106 that are maintained by third parties to the clients 102 or the owners of the clients. The servers 106 may be located off-site in remote geographical locations as disclosed above or otherwise. Public clouds may be connected to the servers 106 over a public network. Private clouds may include private servers 106 that are physically maintained by clients 102 or owners of clients. Private clouds may be connected to the servers 106 over a private network 104. Hybrid clouds 108 may include both the private and public networks 104 and servers 106.

The cloud 108 may also include a cloud based delivery, e.g. Software as a Service (SaaS) 110, Platform as a Service (PaaS) 112, and Infrastructure as a Service (IaaS) 114. IaaS may refer to a user renting the use of infrastructure resources that are needed during a specified time period. IaaS providers may offer storage, networking, servers or virtualization resources from large pools, allowing the users to quickly scale up by accessing more resources as needed. Examples of IaaS can include infrastructure and services (e.g., EG-32) provided by OVH HOSTING of Montreal, Quebec, Canada, AMAZON WEB SERVICES provided by Amazon.com, Inc., of Seattle, Wash., RACKSPACE CLOUD provided by Rackspace US, Inc., of San Antonio, Tex., Google Compute Engine provided by Google Inc. of Mountain View, Calif., or RIGHTSCALE provided by RightScale, Inc., of Santa Barbara, Calif. PaaS providers may offer functionality provided by IaaS, including, e.g., storage, networking, servers or virtualization, as well as additional resources such as, e.g., the operating system, middleware, or runtime resources. Examples of PaaS include WINDOWS AZURE provided by Microsoft Corporation of Redmond, Wash., Google App Engine provided by Google Inc., and HEROKU provided by Heroku, Inc. of San Francisco, Calif. SaaS providers may offer the resources that PaaS provides, including storage, networking, servers, virtualization, operating system, middleware, or runtime resources. In some embodiments, SaaS providers may offer additional resources including, e.g., data and application resources. Examples of SaaS include GOOGLE APPS provided by Google Inc., SALESFORCE provided by Salesforce.com Inc. of San Francisco, Calif., or OFFICE 365 provided by Microsoft Corporation. Examples of SaaS may also include data storage providers, e.g. DROPBOX provided by Dropbox, Inc. of San Francisco, Calif., Microsoft SKYDRIVE provided by Microsoft Corporation, Google Drive provided by Google Inc., or Apple ICLOUD provided by Apple Inc. of Cupertino, Calif.

Clients 102 may access IaaS resources with one or more IaaS standards, including, e.g., Amazon Elastic Compute Cloud (EC2), Open Cloud Computing Interface (OCCI), Cloud Infrastructure Management Interface (CIMI), or OpenStack standards. Some IaaS standards may allow clients access to resources over HTTP, and may use Representational State Transfer (REST) protocol or Simple Object Access Protocol (SOAP). Clients 102 may access PaaS resources with different PaaS interfaces. Some PaaS interfaces use HTTP packages, standard Java APIs, JavaMail API, Java Data Objects (JDO), Java Persistence API (JPA), Python APIs, web integration APIs for different programming languages including, e.g., Rack for Ruby, WSGI for Python, or PSGI for Perl, or other APIs that may be built on REST, HTTP, XML, or other protocols. Clients 102 may access SaaS resources through the use of web-based user interfaces, provided by a web browser (e.g. GOOGLE CHROME, Microsoft INTERNET EXPLORER, or Mozilla Firefox provided by Mozilla Foundation of Mountain View, Calif.). Clients 102 may also access SaaS resources through smartphone or tablet applications, including, e.g., Salesforce Sales Cloud, or Google Drive app. Clients 102 may also access SaaS resources through the client operating system, including, e.g., Windows file system for DROPBOX.

In some embodiments, access to IaaS, PaaS, or SaaS resources may be authenticated. For example, a server or authentication server may authenticate a user via security certificates, HTTPS, or API keys. API keys may include various encryption standards such as, e.g., Advanced Encryption Standard (AES). Data resources may be sent over Transport Layer Security (TLS) or Secure Sockets Layer (SSL).

The client 102 and server 106 may be deployed as and/or executed on any type and form of computing device, e.g. a computer, network device or appliance capable of communicating on any type and form of network and performing the operations described herein. FIGS. 1C and 1D depict block diagrams of a computing device 100 useful for practicing an embodiment of the client 102 or a server 106. As shown in FIGS. 1C and 1D, each computing device 100 includes a central processing unit 121, and a main memory unit 122. As shown in FIG. 1C, a computing device 100 may include a storage device 128, an installation device 116, a network interface 118, an I/O controller 123, display devices 124a-124n, a keyboard 126 and a pointing device 127, e.g. a mouse. The storage device 128 may include, without limitation, an operating system, software, and a software of an industrial protocol converter 120. As shown in FIG. 1D, each computing device 100 may also include additional optional elements, e.g. a memory port 103, a bridge 170, one or more input/output devices 130a-130n (generally referred to using reference numeral 130), and a cache memory 140 in communication with the central processing unit 121.

The central processing unit 121 is any logic circuitry that responds to and processes instructions fetched from the main memory unit 122. In many embodiments, the central processing unit 121 is provided by a microprocessor unit, e.g.: those manufactured by Intel Corporation of Mountain View, Calif.; those manufactured by Motorola Corporation of Schaumburg, Ill.; the ARM processor and TEGRA system on a chip (SoC) manufactured by Nvidia of Santa Clara, Calif.; the POWER7 processor, those manufactured by International Business Machines of White Plains, N.Y.; or those manufactured by Advanced Micro Devices of Sunnyvale, Calif. The computing device 100 may be based on any of these processors, or any other processor capable of operating as described herein. The central processing unit 121 may utilize instruction level parallelism, thread level parallelism, different levels of cache, and multi-core processors. A multi-core processor may include two or more processing units on a single computing component. Examples of multi-core processors include the AMD PHENOM IIX2, INTEL CORE i5 and INTEL CORE i7.

Main memory unit 122 may include one or more memory chips capable of storing data and allowing any storage location to be directly accessed by the microprocessor 121. Main memory unit 122 may be volatile and faster than storage 128 memory. Main memory units 122 may be Dynamic random access memory (DRAM) or any variants, including static random access memory (SRAM), Burst SRAM or SynchBurst SRAM (B SRAM), Fast Page Mode DRAM (FPM DRAM), Enhanced DRAM (EDRAM), Extended Data Output RAM (EDO RAM), Extended Data Output DRAM (EDO DRAM), Burst Extended Data Output DRAM (BEDO DRAM), Single Data Rate Synchronous DRAM (SDR SDRAM), Double Data Rate SDRAM (DDR SDRAM), Direct Rambus DRAM (DRDRAM), or Extreme Data Rate DRAM (XDR DRAM). In some embodiments, the main memory 122 or the storage 128 may be non-volatile; e.g., non-volatile read access memory (NVRAM), flash memory non-volatile static RAM (nvSRAM), Ferroelectric RAM (FeRAM), Magnetoresistive RAM (MRAM), Phase-change memory (PRAM), conductive-bridging RAM (CBRAM), Silicon-Oxide-Nitride-Oxide-Silicon (SONOS), Resistive RAM (RRAM), Racetrack, Nano-RAM (NRAM), or Millipede memory. The main memory 122 may be based on any of the above described memory chips, or any other available memory chips capable of operating as described herein. In the embodiment shown in FIG. 1C, the processor 121 communicates with main memory 122 via a system bus 150 (described in more detail below). FIG. 1D depicts an embodiment of a computing device 100 in which the processor communicates directly with main memory 122 via a memory port 103. For example, in FIG. 1D the main memory 122 may be DRDRAM.

FIG. 1D depicts an embodiment in which the main processor 121 communicates directly with cache memory 140 via a secondary bus, sometimes referred to as a backside bus. In other embodiments, the main processor 121 communicates with cache memory 140 using the system bus 150. Cache memory 140 typically has a faster response time than main memory 122 and is typically provided by SRAM, BSRAM, or EDRAM. In the embodiment shown in FIG. 1D, the processor 121 communicates with various I/O devices 130 via a local system bus 150. Various buses may be used to connect the central processing unit 121 to any of the I/O devices 130, including a PCI bus, a PCI-X bus, or a PCI-Express bus, or a NuBus. For embodiments in which the I/O device is a video display 124, the processor 121 may use an Advanced Graphics Port (AGP) to communicate with the display 124 or the I/O controller 123 for the display 124. FIG. 1D depicts an embodiment of a computer 100 in which the main processor 121 communicates directly with I/O device 130b or other processors 121′ via HYPERTRANSPORT, RAPIDIO, or INFINIBAND communications technology. FIG. 1D also depicts an embodiment in which local busses and direct communication are mixed: the processor 121 communicates with I/O device 130a using a local interconnect bus while communicating with I/O device 130b directly.

A wide variety of I/O devices 130a-130n may be present in the computing device 100. Input devices may include keyboards, mice, trackpads, trackballs, touchpads, touch mice, multi-touch touchpads and touch mice, microphones, multi-array microphones, drawing tablets, cameras, single-lens reflex camera (SLR), digital SLR (DSLR), CMOS sensors, accelerometers, infrared optical sensors, pressure sensors, magnetometer sensors, angular rate sensors, depth sensors, proximity sensors, ambient light sensors, gyroscopic sensors, or other sensors. Output devices may include video displays, graphical displays, speakers, headphones, inkjet printers, laser printers, and 3D printers.

Devices 130a-130n may include a combination of multiple input or output devices, including, e.g., Microsoft KINECT, Nintendo Wiimote for the WII, Nintendo WII U GAMEPAD, or Apple IPHONE. Some devices 130a-130n allow gesture recognition inputs through combining some of the inputs and outputs. Some devices 130a-130n provides for facial recognition which may be utilized as an input for different purposes including authentication and other commands. Some devices 130a-130n provides for voice recognition and inputs, including, e.g., Microsoft KINECT, SIRI for IPHONE by Apple, Google Now or Google Voice Search.

Additional devices 130a-130n have both input and output capabilities, including, e.g., haptic feedback devices, touchscreen displays, or multi-touch displays. Touchscreen, multi-touch displays, touchpads, touch mice, or other touch sensing devices may use different technologies to sense touch, including, e.g., capacitive, surface capacitive, projected capacitive touch (PCT), in-cell capacitive, resistive, infrared, waveguide, dispersive signal touch (DST), in-cell optical, surface acoustic wave (SAW), bending wave touch (BWT), or force-based sensing technologies. Some multi-touch devices may allow two or more contact points with the surface, allowing advanced functionality including, e.g., pinch, spread, rotate, scroll, or other gestures. Some touchscreen devices, including, e.g., Microsoft PIXELSENSE or Multi-Touch Collaboration Wall, may have larger surfaces, such as on a table-top or on a wall, and may also interact with other electronic devices. Some I/O devices 130a-130n, display devices 124a-124n or group of devices may be augment reality devices. The I/O devices may be controlled by an I/O controller 123 as shown in FIG. 1C. The I/O controller may control one or more I/O devices, such as, e.g., a keyboard 126 and a pointing device 127, e.g., a mouse or optical pen. Furthermore, an I/O device may also provide storage and/or an installation medium 116 for the computing device 100. In still other embodiments, the computing device 100 may provide USB connections (not shown) to receive handheld USB storage devices. In further embodiments, an I/O device 130 may be a bridge between the system bus 150 and an external communication bus, e.g. a USB bus, a SCSI bus, a FireWire bus, an Ethernet bus, a Gigabit Ethernet bus, a Fibre Channel bus, or a Thunderbolt bus.

In some embodiments, display devices 124a-124n may be connected to I/O controller 123. Display devices may include, e.g., liquid crystal displays (LCD), thin film transistor LCD (TFT-LCD), blue phase LCD, electronic papers (e-ink) displays, flexile displays, light emitting diode displays (LED), digital light processing (DLP) displays, liquid crystal on silicon (LCOS) displays, organic light-emitting diode (OLED) displays, active-matrix organic light-emitting diode (AMOLED) displays, liquid crystal laser displays, time-multiplexed optical shutter (TMOS) displays, or 3D displays. Examples of 3D displays may use, e.g. stereoscopy, polarization filters, active shutters, or autostereoscopy. Display devices 124a-124n may also be a head-mounted display (HMD). In some embodiments, display devices 124a-124n or the corresponding I/O controllers 123 may be controlled through or have hardware support for OPENGL or DIRECTX API or other graphics libraries.

In some embodiments, the computing device 100 may include or connect to multiple display devices 124a-124n, which each may be of the same or different type and/or form. As such, any of the I/O devices 130a-130n and/or the I/O controller 123 may include any type and/or form of suitable hardware, software, or combination of hardware and software to support, enable or provide for the connection and use of multiple display devices 124a-124n by the computing device 100. For example, the computing device 100 may include any type and/or form of video adapter, video card, driver, and/or library to interface, communicate, connect or otherwise use the display devices 124a-124n. In one embodiment, a video adapter may include multiple connectors to interface to multiple display devices 124a-124n. In other embodiments, the computing device 100 may include multiple video adapters, with each video adapter connected to one or more of the display devices 124a-124n. In some embodiments, any portion of the operating system of the computing device 100 may be configured for using multiple displays 124a-124n. In other embodiments, one or more of the display devices 124a-124n may be provided by one or more other computing devices 100a or 100b connected to the computing device 100, via the network 104. In some embodiments software may be designed and constructed to use another computer's display device as a second display device 124a for the computing device 100. For example, in one embodiment, an Apple iPad may connect to a computing device 100 and use the display of the device 100 as an additional display screen that may be used as an extended desktop. One ordinarily skilled in the art will recognize and appreciate the various ways and embodiments that a computing device 100 may be configured to have multiple display devices 124a-124n.

Referring again to FIG. 1C, the computing device 100 may comprise a storage device 128 (e.g. one or more hard disk drives or redundant arrays of independent disks) for storing an operating system or other related software, and for storing application software programs such as any program related to the software for the screenshot linking system 120. Examples of storage device 128 include, e.g., hard disk drive (HDD); optical drive including CD drive, DVD drive, or BLU-RAY drive; solid-state drive (SSD); USB flash drive; or any other device suitable for storing data. Some storage devices may include multiple volatile and non-volatile memories, including, e.g., solid state hybrid drives that combine hard disks with solid state cache. Some storage device 128 may be non-volatile, mutable, or read-only. Some storage device 128 may be internal and connect to the computing device 100 via a bus 150. Some storage devices 128 may be external and connect to the computing device 100 via an I/O device 130 that provides an external bus. Some storage device 128 may connect to the computing device 100 via the network interface 118 over a network 104, including, e.g., the Remote Disk for MACBOOK AIR by Apple. Some client devices 100 may not require a non-volatile storage device 128 and may be thin clients or zero clients 102. Some storage device 128 may also be used as an installation device 116, and may be suitable for installing software and programs. Additionally, the operating system and the software can be run from a bootable medium, for example, a bootable CD, e.g. KNOPPIX, a bootable CD for GNU/Linux that is available as a GNU/Linux distribution from knoppix.net.

Client device 100 may also install software or application from an application distribution platform. Examples of application distribution platforms include the App Store for iOS provided by Apple, Inc., the Mac App Store provided by Apple, Inc., GOOGLE PLAY for Android OS provided by Google Inc., Chrome Webstore for CHROME OS provided by Google Inc., and Amazon Appstore for Android OS and KINDLE FIRE provided by Amazon.com, Inc. An application distribution platform may facilitate installation of software on a client device 102. An application distribution platform may include a repository of applications on a server 106 or a cloud 108, which the clients 102a-102n may access over a network 104. An application distribution platform may include application developed and provided by various developers. A user of a client device 102 may select, purchase and/or download an application via the application distribution platform.

Furthermore, the computing device 100 may include a network interface 118 to interface to the network 104 through a variety of connections including, but not limited to, standard telephone lines LAN or WAN links (e.g., 802.11, T1, T3, Gigabit Ethernet, Infiniband), broadband connections (e.g., ISDN, Frame Relay, ATM, Gigabit Ethernet, Ethernet-over-SONET, ADSL, VDSL, BPON, GPON, fiber optical including FiOS), wireless connections, or some combination of any or all of the above. Connections can be established using a variety of communication protocols (e.g., TCP/IP, Ethernet, ARCNET, SONET, SDH, Fiber Distributed Data Interface (FDDI), IEEE 802.11a/b/g/n/ac CDMA, GSM, WiMax and direct asynchronous connections). In one embodiment, the computing device 100 communicates with other computing devices 100′ via any type and/or form of gateway or tunneling protocol e.g. Secure Socket Layer (SSL) or Transport Layer Security (TLS), or the Citrix Gateway Protocol manufactured by Citrix Systems, Inc. of Ft. Lauderdale, Fla. The network interface 118 may comprise a built-in network adapter, network interface card, PCMCIA network card, EXPRESSCARD network card, card bus network adapter, wireless network adapter, USB network adapter, modem or any other device suitable for interfacing the computing device 100 to any type of network capable of communication and performing the operations described herein.

A computing device 100 of the sort depicted in FIGS. 1B and 1C may operate under the control of an operating system, which controls scheduling of tasks and access to system resources. The computing device 100 can be running any operating system such as any of the versions of the MICROSOFT WINDOWS operating systems, the different releases of the Unix and Linux operating systems, any version of the MAC OS for Macintosh computers, any embedded operating system, any real-time operating system, any open source operating system, any proprietary operating system, any operating systems for mobile computing devices, or any other operating system capable of running on the computing device and performing the operations described herein. Typical operating systems include, but are not limited to: WINDOWS 2000, WINDOWS Server 2022, WINDOWS CE, WINDOWS Phone, WINDOWS XP, WINDOWS VISTA, and WINDOWS 7, WINDOWS RT, and WINDOWS 8 all of which are manufactured by Microsoft Corporation of Redmond, Wash.; MAC OS and iOS, manufactured by Apple, Inc. of Cupertino, Calif.; and Linux, a freely-available operating system, e.g. Linux Mint distribution (“distro”) or Ubuntu, distributed by Canonical Ltd. of London, United Kingdom; or Unix or other Unix-like derivative operating systems; and Android, designed by Google, of Mountain View, Calif., among others. Some operating systems, including, e.g., the CHROME OS by Google, may be used on zero clients or thin clients, including, e.g., CHROMEBOOKS.

The computer system 100 can be any workstation, telephone, desktop computer, laptop or notebook computer, netbook, ULTRABOOK, tablet, server, handheld computer, mobile telephone, smartphone or other portable telecommunications device, media playing device, a gaming system, mobile computing device, or any other type and/or form of computing, telecommunications or media device that is capable of communication. The computer system 100 has sufficient processor power and memory capacity to perform the operations described herein. In some embodiments, the computing device 100 may have different processors, operating systems, and input devices consistent with the device. The Samsung GALAXY smartphones, e.g., operate under the control of Android operating system developed by Google, Inc. GALAXY smartphones receive input via a touch interface.

In some embodiments, the computing device 100 is a gaming system. For example, the computer system 100 may comprise a PLAYSTATION 3, or PERSONAL PLAYSTATION PORTABLE (PSP), or a PLAYSTATION VITA device manufactured by the Sony Corporation of Tokyo, Japan, a NINTENDO DS, NINTENDO 3DS, NINTENDO WII, or a NINTENDO WII U device manufactured by Nintendo Co., Ltd., of Kyoto, Japan, an XBOX 360 device manufactured by the Microsoft Corporation of Redmond, Wash.

In some embodiments, the computing device 100 is a digital audio player such as the Apple IPOD, IPOD Touch, and IPOD NANO lines of devices, manufactured by Apple Computer of Cupertino, Calif. Some digital audio players may have other functionality, including, e.g., a gaming system or any functionality made available by an application from a digital application distribution platform. For example, the IPOD Touch may access the Apple App Store. In some embodiments, the computing device 100 is a portable media player or digital audio player supporting file formats including, but not limited to, MP3, WAV, M4A/AAC, WMA Protected AAC, AIFF, Audible audiobook, Apple Lossless audio file formats and .mov, .m4v, and .mp4 MPEG-4 (H.264/MPEG-4 AVC) video file formats.

In some embodiments, the computing device 100 is a tablet e.g. the IPAD line of devices by Apple; GALAXY TAB family of devices by Samsung; or KINDLE FIRE, by Amazon.com, Inc. of Seattle, Wash. In other embodiments, the computing device 100 is an eBook reader, e.g. the KINDLE family of devices by Amazon.com, or NOOK family of devices by Barnes & Noble, Inc. of New York City, N.Y.

In some embodiments, the communications device 102 includes a combination of devices, e.g. a smartphone combined with a digital audio player or portable media player. For example, one of these embodiments is a smartphone, e.g. the IPHONE family of smartphones manufactured by Apple, Inc.; a Samsung GALAXY family of smartphones manufactured by Samsung, Inc.; or a Motorola DROID family of smartphones. In yet another embodiment, the communications device 102 is a laptop or desktop computer equipped with a web browser and a microphone and speaker system, e.g. a telephony headset. In these embodiments, the communications devices 102 are web-enabled and can receive and initiate phone calls. In some embodiments, a laptop or desktop computer is also equipped with a webcam or other video capture device that enables video chat and video call.

In some embodiments, the status of one or more machines 102, 106 in the network 104 are monitored, generally as part of network management. In one of these embodiments, the status of a machine may include an identification of load information (e.g., the number of processes on the machine, CPU and memory utilization), of port information (e.g., the number of available communication ports and the port addresses), or of session status (e.g., the duration and type of processes, and whether a process is active or idle). In another of these embodiments, this information may be identified by a plurality of metrics, and the plurality of metrics can be applied at least in part towards decisions in load distribution, network traffic management, and network failure recovery as well as any aspects of operations of the present solution described herein. Aspects of the operating environments and components described above will become apparent in the context of the systems and methods disclosed herein.

B. Industrial Protocol Converters

Large manufacturing and process plants use low level field protocols to communicate between various sensors, actuators, controllers and human-machine interface (HMI)/Dashboard systems. There are approximately 300 such field level protocols which use serial, fieldbus, USB, Ethernet, and wireless physical layers to transmit low bandwidth data amongst various industrial systems. With emergence of Industrial IoT there is a significant need to pull data from these systems and push it to cloud for remote data collection, visualization and analytics.

All these protocols carry 3 types of data; Numerical data from sensors and counters, events from controllers and actuators and control commands to manage the processes. Even though information carried by these field protocols is identical, they use different packet and transmission structure. This makes tapping and data capture from field networks a technology challenge. In industrial IoT architecture, a hardware gateway device that resides in the field reads data from these protocols, converts into a language that internet understands (e.g., Restful API, MQTT) and pushes this information over the internet to a remote cloud server. As there are 300 different protocols designing a new firmware from scratch for each protocol is time consuming and expensive task.

As a solution to this problem, the following discussion presents a new architecture where blocks associated with data buffering and storage, configuration, local data visualization, communication with internet remain identical for each protocol. Only Lowermost layer of driver which actually fetches the data from field networks, changes from one protocol to another. This new architecture provides benefits such as limited code fragmentation, improved system reusability, faster implementation of new protocol driver and improved hardware performance.

One aspect of this architecture is in memory cache which acts as buffer and storage between driver and other blocks as discussed below. As driver is isolated from other system blocks and can only communicate with other pieces of the software through in-memory persistent cache, the driver can be written in a different coding language compared to other software blocks.

The following discussion introduces micro-service architecture for embedded gateways. The discussion includes in-memory databases and their interfacing techniques in order to improve reliability and performance of system. This solution also solves problems as of persistence and threads handling.

Challenges associated with advanced embedded gateways include: supporting diverse protocols higher level like OPC; MTConnect and lower level like Modbus and EthernetIP and building bottom to top solution and maintain them; all low memory footprint databases face challenges on threading side; coupling and bottlenecks in between components and their communication; providing management user interface (UI) in this system, for providing over the intranet access we really have less small memory footprint choices; explicitly handling historics data part; wrong roles and responsibilities, for example, in terms of low level protocols, driver initiates and handles data sending part with data sampling; for large datasets, fetch operation would take a significant amount of time, leading to timeout exceptions in multithreaded environments and longer loading times for the UI; in case of abrupt power cycles, the database itself would get corrupted; no support for arbitrary datatypes i.e. if we had nested objects, we had to make separate tables for each sub object; no bandwidth for validations and other checks like duplication of data; there is no security standards applied; and edge analytics is difficult to perform because of the no bandwidth on processor cycles.

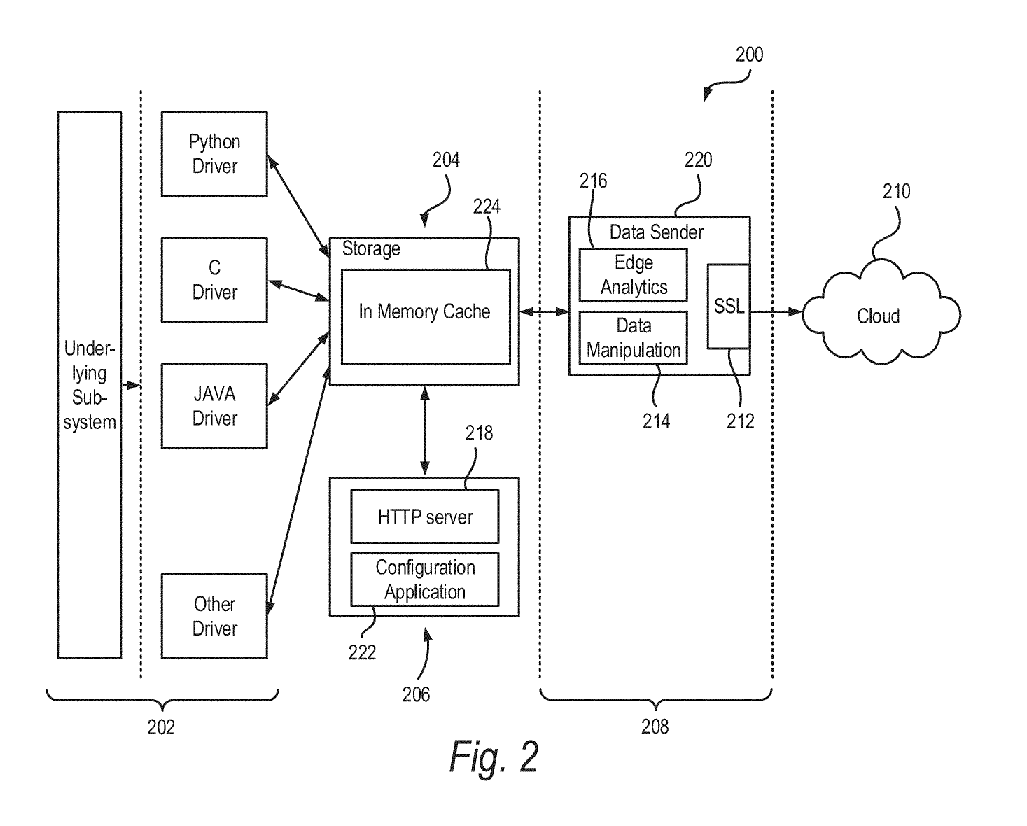

FIG. 2 shows a block diagram of an example micro-service architecture for embedded gateways 200. In this architecture, the roles and responsibilities are clearly separated out. A micro-services architecture is created without exposing functionality explicitly. The architecture has four sections: Collection 202, Storage 204, Configuration 206, and Manipulation & Communication 208.

Manipulation and Communication

The manipulation and communication layer 208 is mainly responsible for retrieving data from storage and sending it to a remote server, such as, for example, an external cloud 210 over a network, such as, for example the internet. This can even manipulate data using edge analytics 212 features and responsible for maintaining the state of data locally. There are 2 components in this layer: Cloud 210 and Data Sender 220. This section can be common across protocols.

Cloud: The cloud 210 contains cloud stack from any of the service providers or in-house servers. Service providers can include, for example, Amazon Main responsibility of cloud is to receive data from the gateway 200, store it in an effective way and provide processes on data such as analytics, stream processing, etc.

Data Sender: The data sender 220 is the main interface between cloud and the embedded gateway 200. It can contain various modules such as a secure socket layer (SSL) module 212, a data manipulation module 214, and an edge analytics module 216. The SSL module 212 can provide a secure socket layer network communication between the embedded gateway 200 and the cloud 210. The edge analytics module 216 can analyze sensor data before it is transmitted to the cloud 210. For example, the edge analytics module 216 can filter the sensor data based on parameters such as time, value, source, etc., such that only the relevant data is sent to the cloud 210. This can improve the performance of the gateway 200 by reducing the amount of network traffic between the gateway and the cloud 210, and can also reduce the amount of storage needed at the cloud 210. The data manipulation module 214 can modify the data before being transmitted to the cloud 210. For example, the data manipulation module can change the units of the values, compress the sensor data, and carry out other data manipulations. As an example compressing the sensor data before transmission to the cloud 210 can improve the performance of the gateway 200 by reducing the amount of network traffic between the gateway 200 and the cloud 210. The data sender 220 can have a one way communication to the cloud 210 and may not allow to communicate back from the cloud to the components on the other side of the data sender 220. This can improve the security of the gateway 200 by isolating the storage 204 and the configuration 206 from the external cloud 210. In some embodiments, the data sender 220 can be implemented as a different process which will run independently of other processes on gateway 200.

Configuration

The configuration section 206 can provide a secure and efficient way for users to configure the gateway 200 and see diagnostic information. Again this section can be common across the protocols, with some dynamic backend support to create pages as per protocol. The configuration section 206 can communicate with the storage 204 to access configuration data of the gateway 200.

HTTP Server: A HTTP server 218 acts as a container and provides accessibility anywhere in intranet. Users can login into the gateway 200 if they are connected to local intranet through the HTTP server 218, and configure the gateway 200.

Configuration Application: A configuration application 222 can run under the HTTP server 218 and it can be custom application as per user needs. Responsibilities it handles are: 1. Provide better way for viewing and modifying gateway configuration using dynamic web pages, 2. Store configurations which the use can efficiently modify, 3. Ensure that the configuration settings are applied to the gateway 200 wherever needed, and 4. Get necessary information regarding the configuration data from storage 204 whenever requested. The configuration application can present a configuration user interface in the form of a dynamic webpage, which the user can utilize for viewing and modifying configuration data of the gateway 200. The configuration application 222 can provide an application programmable interface, such as a REST API to allow an external application, such as a web application, to communicate with the configuration application 222 and request read or writes of the configuration data of the gateway 200.This module containing a HTTP server 218 and a configuration application 222 can run independently of other processes in the gateway 200.

Storage

The storage 204 is responsible for providing a way to efficiently store and retrieve data.

In-memory Cache: The storage can include an in-memory cache 224. In some instances, the in-memory cache can be an in-memory persistent database. For sensors, limited resources such as memory and flash media are a bottleneck, since the sensors typically produce data streams that originate from a single source. For IoT gateways, write performance with concurrent read access is important because the gateway 200 will likely collect data from a number of sensors or similar devices. For mobile devices, the main bottleneck is the availability of data when there is no connection. For embedded systems, interoperability and maintainability of these subsystems are very important.

in some implementations, there can be a tendency to use small memory footprint relational databases for storing relational and sensor data, or use file storage. However, both of these approaches come with their own drawbacks.

The in-memory caches 224 can have persistence and publish/subscribe capability. For example, in some implementations, an in-memory persistent data structure such as, for example, REDIS can be utilized, which is known to be well proven and tested for efficiency, small memory footprint and auto persistence. The in-memory cache 224 is discussed further below.

Collection

The collection section 202 handles data collection from underlying subsystems. The underlying subsystems can include a number of sensors, actuators, or other devices. Due to the variety of communication protocols associated with various devices, the underlying subsystem can operate over a variety of communication protocols.

Driver: A driver is responsible for collection of data from underlying subsystem. The process of communicating with a sensor or other device may vary depending on the communication protocol utilized by the particular sensor or device For example, the driver can be a Python driver that uses python to communicate with a sensor or device, or a C driver, that uses C language to communicate with the sensor or device, or a JAVA driver that uses JAVA to communicate with the sensor or driver, or other drivers using other communication protocols. As discussed further below, the drivers can convert the communication protocols

In terms of code maintenance, there can be multiple drivers depending on different protocols and they can be even implemented using different technology than data sender 220 and configuration application 222.

Implementation Details

In order to implement the gateway 200 architecture, some of the objects that will be used by the drivers, a webapp and the data sender 220 have been identified and classified. In some implementations, the embedded application can be split into three different elements, allowing for ease in debugging, and saving development time having to only modify the drivers whenever a new protocol is introduced, and precluding any changes to the remainder of the gateway 200. As an example, storage objects such as configuration, data pipeline, and flags can be utilized.

Configuration

Configuration data includes the settings that are configurable and reside in the in-memory persistent database 224 for relatively longer periods of time. The different components of the gateway 200 firmware adhere to these configuration settings and fetch/push data accordingly. For the configuration, an advanced publish-subscribe mechanism can be utilized where, if one component changes, the other components are automatically notified of the change. In addition, the configuration settings are non-volatile and will persist after a gateway 200 reboot.

The configuration data can be set by the user via the webapp that interfaces with the in-memory persistent database 224. configuration data can include configuration for hubs, sensors, events and conditions. A hub can refer to a set of sensor or devices. A hub can represent a set of sensor or devices that are geographically local. In some instances, a hub can represent a set of sensors or devices of the same type. In some other instances, a hub can represent a set of sensors or devices communicating with the same communication protocol. The configuration data can be stored in relation to the hub, and can include configuration data associated with the constituent sensors or devices. The configuration data can be stored in a configuration data structure such as, for example, in a single object, examples of which include a JSON String. The configuration data associated with a hub can be hashed with an API-KEY for the particular hub, and stored in the in-memory persistent database 224 indexed by the API-KEY. This would prevent API-KEY duplication. Also, when someone has to request for the hub configuration, they have to pass the API-key for that hub as a parameter. Every request operation would be performed with API-KEYs.

The in-memory persistent database 224 can provide a common API for accessing configuration data stored therein. The in-memory persistent database 224 can store the configuration data for a hub of sensor or devices indexed by the API-key associated with the hub. The common API can be implemented using any key-value type database, such as, for example, REDIS in-memory data structure store. In one example, the configuration data associated with the hub can be stored as a string field associated with the API-key value. the common API can provide commands such as HGET to retrieve configuration data and HSET to modify or update configuration data in the database.

GET config

| Method | Key | Field | Value |
|---|---|---|---|
| HGET | “hub” | hub.apiKey | JSON(HubTO) |

SET config

| Method | Key | Field | Value |
|---|---|---|---|
| HSET | “hub” | hub.apiKey | JSON(HubTO) |

As illustrated in the above two examples, HGET can be a request to access configuration data associated with the field “hub.apiKey” in the hash stored at the key “hub.” The common API can return the value JSON(HubTO), which can represent a JSON string including the configuration parameters and their corresponding values for the hub. One example of the JSON string is shown below in Table 1. The HSET command can be a request to write or update configuration data associated with a hub stored in the in-memory persistent database 224. The HSET command request can set the field “hub.apiKey” in the hash stored at the key “hub” to the value “JSON(HubTO).” Thus the HSET request can include the key value “hub” in addition to the identity of the field and the string value. Again, the JSON string shown in Table 1 below can be included with the request. The common API in response to receiving the HSET request, can store the string value in the field associate with the provided API key.

In some instances, the common API can also provide commands to retrieve the keys associated with the hubs. In such instances, requesting a hub configuration would be a 2 step process, as follows.

1. Fetch all the api-keys in “hub”: hkeys “hub”

2. Fetch the particular hub: hget “hub” “<api-key>”

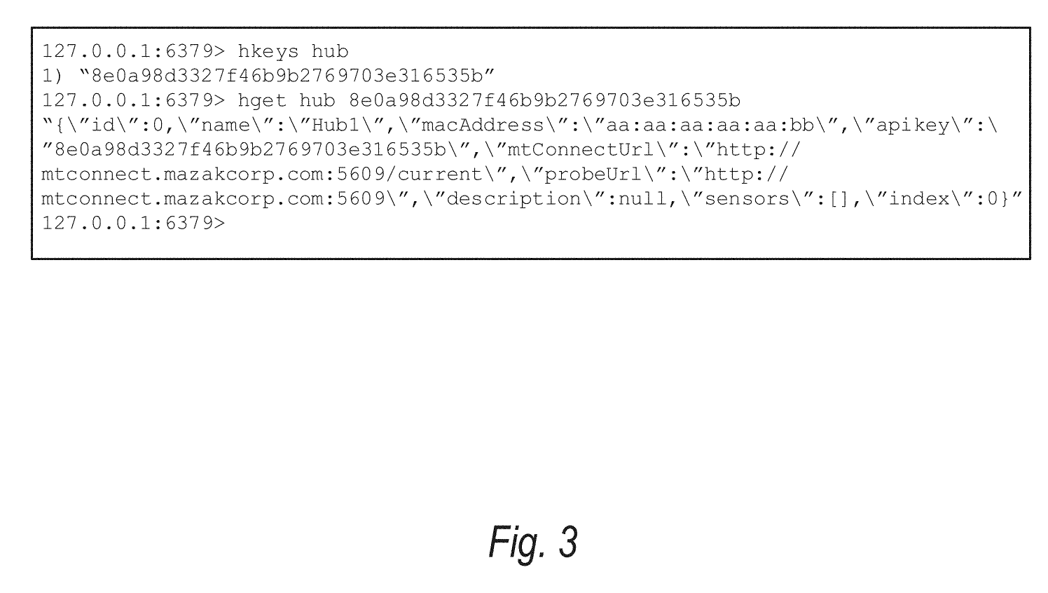

FIG. 3 shows a screenshot of an example process for obtaining the configuration data from the in-memory persistent database 224. In particular, FIG. 3 shows a screenshot of a configuration object for the MTConnect protocol. The in-memory persistent database 224 can provide a command-line interface through which a user can send requests or commands. The first command “hkeys hub” requests the key associated with the “hub”. The in-memory persistent database 224 can retrieve the stored key value associated with hub, and output the retrieved key value. In the following command, the user can request the configuration parameters associated with the “hub” by entering the command “hget hub” followed by the retrieved key value. The in-memory persistent database 224 can use the key value to access the string value stored in association with the key and return the configuration data. In the example shown in FIG. 3, the in-memory persistent database 224 is implemented in REDIS. REDIS automatically converts the character “into escape characters \”. This is purely for display purpose. The actual JSON string would not have escape characters and the quotes at the beginning and the end. Actual hub configuration object might differ from protocol to protocol. JSON parsers will be able to decode the string without any extra modifications.

TABLE 1

| | |
|---|---|
| HubTO | |
| • Name | 1. Name: Hub Name to be displayed |
| • ApiKey | 2. ApiKey: Api key to send on portal |
| • MAC | 3. Mac: Virtual MAC with which API key is linked on portal |
| • Data URL | 4. Data URL: URL from which MTConnect data is pulled |
| • Probe URL | 5. Probe URL: URL from which MTConnect schema is |
| | pulled |
| • Description | 6. Description: Additional info to be displayed |
| • SensorTO | 7. SensorTO: POJO, List of sensors |
| ∘ Asset | 8. Asset: <componentId, name, component> of the desired |
| | stream |
| ∘ Port | 9. Port: Sensor port to send to portal |
| ∘ Sample | 10. Sample: <dataItemId, name, baseTag> of desired sensor |
| ∘ ConditionTO | 11. ConditionTO: POJO, list of conditions |
| ▪ Port | 12. Port: Sensor with which the condition is associated |
| ▪ Name | 13. Name: <dataItemId, name, baseTag> of desired condition |
| ∘ EventTO | 14. EventTO: POJO, list of events |
| ▪ Name | 15. Name: <dataItemId, name, baseTag> of desired event |

Data, Conditions & Events Pipeline

The in-memory persistent database 224 can store data pipeline data structures for storing data associated with the sensors. These are the actual data points that are collected from the protocol driver and reside in memory for relatively shorter periods of time. The protocol driver pushes data, condition events and general events into the respective pipelines, which are then read by the Data Sender 220 and sent to the cloud 210.

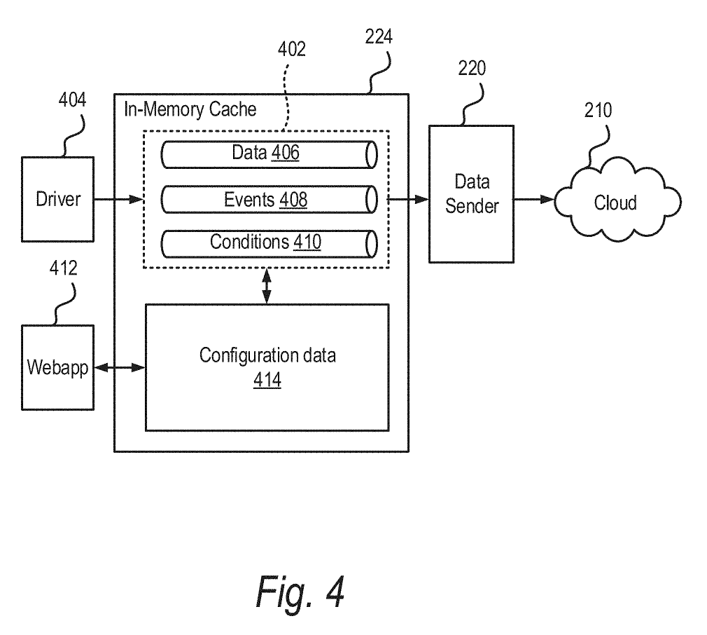

FIG. 4 shows a block diagram representation of an example in-memory cache 224. In particular, the in-memory cache 224 can include a data pipeline data structure 402 associated with a hub or with a set of sensors or devices. The data pipeline data structure 402 can include several pipeline data structures, such as a data pipeline 406, an events pipeline 408, and a conditions pipeline 410. A driver 404 can receive data associated with a set of sensors over a particular communication protocol. While not shown in FIG. 4, additional drivers can receive data associated with other sets of sensors over other communication protocols. The driver 404 can receive data such as sensor measurement data, sensor events data, and sensor conditions data from the set of sensors. The driver can send requests to the in-memory persistent database 224 to store data received from the set of sensors. In response, the in-memory persistent database 224 can store the sensor measurement data in the data pipeline 406, the sensor events data in the events pipeline 408 and the sensor conditions data in the conditions pipeline 410.

The in-memory persistent database 224 can store the data stored in the data pipeline data structure 402 as a sorted set of data values, where the data is sorted based on the time stamp associated with each data value. The driver 404 can provide a series of data values associated with the set of sensors. These data values can include a time stamp field, that indicates the time when the data value was generated. In some instances, the driver 404 may receive data values from the set of sensors out of order, i.e., data values with an earlier time stamp may arrive after data values with a later time stamp. In some other instances, the driver 404 may receive duplicate data values. That is, the driver 404 may receive multiple data values with the same time stamp. In such instances, the driver 404 does not need to be concerned with out of order or duplicate data values. The in-memory persistent database 224 can sort the data values based on the time stamps and ignore data values with duplicate time stamps. This ensures that the data pipeline data structure includes a sorted set of data values that are not duplicate. In some instances, the data pipeline data structure 402 can be implemented using REDIS sorted sets.

Each hub or set of sensors can be assigned a unique data pipeline data structure 402. As an example, each pipeline (406, 408, and 410) can be assigned their own unique API key that is unique for the hub or set of sensors. The driver 404 can utilize the unique API keys with the requests to store the data, events, and conditions in the respective pipelines. Similarly, the data sender 220 can request to pull the data in the pipelines for transmission to the cloud 210. The data sender can send a data pull request via the common API, where the request includes the appropriate API key for the pipeline. Both the driver 404 and the data sender 220 can send multiple respective data push and data pull requests to store sensor data into the pipelines 402 and to pull data for transmission to the cloud 210.

The in-memory persistent database 224 can also store the configuration data 414 discussed above. The in-memory persistent database 224 can provide an API that can be used to read and write the configuration data 414. As mentioned above, in some instances, a REDIS API can be provided for retrieving and updating or writing configuration data associated with a hub or set of sensors using the appropriate API key. A web application 412 can use the API to send read and write requests (such as for example, HGET and HSET commands) to the in-memory persistent database 224 to retrieve configuration data 414 and write or uprate configuration data 414. Configuration data associated with each hub or set of sensors can be stored in a key-value structure in the in-memory persistent database 224. In some instances, in-memory persistent database 224 can be configured to update values of parameters in the configuration data associated with a hub or set of sensors based on data values in the data pipeline 402 associated with the hub or set of sensors. For example, the in-memory persistent database 224 can be configured to update the values of “ConditionTO” and “EventTO” parameters of the configuration data string shown in Table 1 above based on data values received in the data pipeline data structure 402.

The following tables show example commands in the API provided by the in-memory persistent database 224 for pushing, pulling and peeking data values stored in the data pipeline data structure 402. In particular, the following tables show example commands when the in-memory persistent database 224 is implemented based on REDIS. To push data into a pipeline, the driver 404 can utilize the ZADD command including the API-key associated with the particular pipeline for the particular hub or set of sensors. The pipelines are sorted based on the “score” field, which can include the timestamp associated with the data values. Similarly, the data sender 220 can send ZRANGE commands to read data from the desired data pipeline. The data sender 220 can also send a ZREM command subsequent to the ZRANGE command to delete the requested entries from the pipeline, thereby resulting in a data pull operation.

Push data

| Element | Method | Key | Score | Serialized format |
|---|---|---|---|---|
| Data | ZADD | “HD_<API- | <timestamp> | <port>\|<value>\|<timestamp> |
| | | KEY>” | | |
| Conditions | ZADD | “HC_<API- | <timestamp> | <port>\|<messageCode>\|<message |
| Events | | KEY>” | | Type>\|<description>\|<timestamp> |
| General | ZADD | “HE_<API- | <timestamp> | <t1>\|<t2>\|<message>\|<timestamp> |
| Events | | KEY>” | | |

Pull data (Peek)

| Element | Method | Key |
|---|---|---|
| Data | ZRANGE | “HD_<API-KEY>” |
| Conditions | ZRANGE | “HC_<API-KEY>” |
| Events | ZRANGE | “HE_<API-KEY>” |

Pull data (Pop)

| Element | Method | Key |
|---|---|---|
| Data | ZRANGE | “HD_<API-KEY>” |
| | ZREM | <peeked data point> |
| Conditions | ZRANGE | “HC_<API-KEY>” |
| | ZREM | <peeked data point> |
| Events | ZRANGE | “HE_<API-KEY>” |
| | ZREM | <peeked data point> |

Flags

These are general purpose flags that denote the status of working of each of the applications. They incorporate an advanced publish-subscribe mechanism to notify other processes of the same.

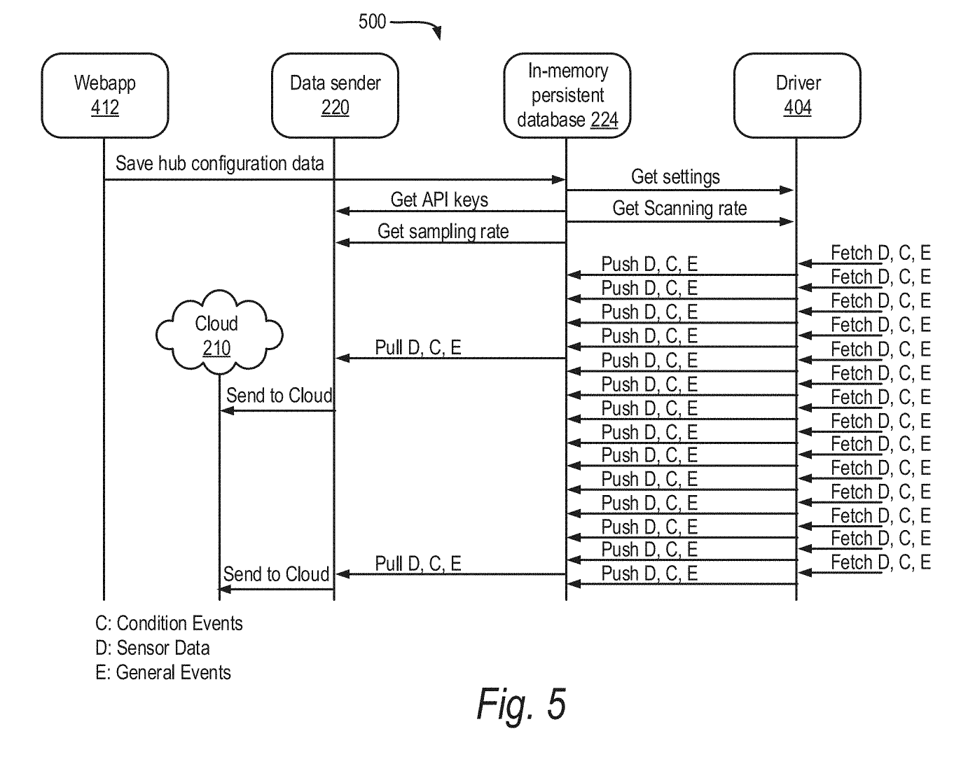

FIG. 5 shows an example inter-processor communication diagram 500. Each of the vertical lines show the life cycle of the processes running in the processor. Each horizontal line shows communication between various processes. All the data transaction processes either start or terminate with the in-memory persistent database 224 except for the one with the cloud 210. The inter-processor communication diagram 500 shows communications between a driver 404, an in-memory persistent storage 224, a data sender 220, a webapp 412, and the cloud 210. The webapp 412 can utilize the API provided by the in-memory persistent database 224 to store configuration data associated with a hub or set of sensors. The in-memory persistent database 224 can communicate with the driver 404 to obtain settings and scanning rate data. The settings can indicate the settings of the set of sensors, while the scanning rate can indicate the rate at which the driver scans the sensors and sends data to the in-memory persistent database 224. This information can be useful to ensure that the expected rate and amount of data complies with the processing speed and size (e.g., pipeline depth) of the in-memory persistent database 224. The data sender 220 can request API keys and sampling rate from the in-memory persistent database 224.

The driver 402 can fetch data such as condition data, sensor data, and events data from a hub or set of sensors. The driver 402 can utilize one or more communication protocols to fetch the data from the set of sensors. The driver 402 also can utilize the common API provided by the in-memory persistent database 224 to store the conditions, sensor data, and the events in the appropriate pipelines. Subsequently, the data sender 220 also can utilize the common API to pull the conditions, sensor data, and events stored in the pipelines, and send the pulled data to the cloud 210. The data sender 220 may carry out data manipulation and edge analytics prior to sending the pulled data to the cloud 210.

There are several advantages associated with the architecture discussed above, which include 1. Vastly improved read/write speeds and create, read, update, and delete (CRUD) operations, 2. Robust support for multithreaded applications, 3. Reduced overall number of read/write operations on the underlying disk because changes in memory are flushed to disk on demand, 4. Native support for sets, so data points are not duplicated, and 5. Support to store runtime artifacts for a highly scalable distributed system.

What is claimed is:

1. A method for managing data at a gateway device receiving sensor data, comprising:
receiving, at a plurality of drivers, sensor data, each of the plurality of drivers receiving sensor data over a different communication protocol,
providing, by an in-memory persistent database, a common API to the plurality of drivers;
receiving, by the in-memory persistent database, via the common API, a data store request from at least one driver from the plurality of drivers, the data store request including a first API key unique to a first set of sensors;
storing, by the in-memory persistent database, data received from the at least one driver in at least one data pipeline data structure, the at least one data pipeline data structure indexed by the first API key;
receiving, by the in-memory persistent database from a data sender application via the common API, a data pull request including the first API key;
providing, by the in-memory persistent database, data stored in the data pipeline data structure indexed by the first API key to the data sender application; and
transmitting, by the data sender application to a remote server, the data stored in the data pipeline structure provided by the in-memory persistent database.

2. The method of claim 1, wherein the at least one data pipeline data structure includes a data pipeline, and wherein storing, by the in-memory persistent database, data received from the at least one driver in the at least one data pipeline data structure includes storing sensor data received from the at least one driver in the data pipeline.

3. The method of claim 1, wherein the at least one data pipeline data structure includes an events pipeline, and wherein storing, by the in-memory persistent database, data received from the at least one driver in the at least one data pipeline data structure includes storing sensor events data received from the at least one driver in the events pipeline.

4. The method of claim 1, wherein the at least one data pipeline data structure includes a conditions pipeline, and wherein storing, by the in-memory persistent database, data received from the at least one driver in the at least one data pipeline data structure includes storing sensor conditions data received from the at least one driver in the conditions pipeline.

5. The method of claim 1, wherein storing, by the in-memory persistent database, data in the at least one data pipeline data structure includes storing data in a sorted set based on time stamps associated with the data.

6. The method of claim 1, further comprising, storing on demand, by the in-memory persistent database, data in the at least one data pipeline data structure in a non-volatile disc.

7. The method of claim 1, further comprising, receiving, by the in-memory persistent database, an application layer store request to store configuration data, the request including a second API key unique to the first set of sensors and configuration data, and storing, by the in-memory persistent database, the configuration data in a configuration data structure indexed by the second API key.

8. The method of claim 7, wherein the configuration data is in JSON format, and wherein storing the configuration data in a configuration data structure includes storing the configuration data in the received JSON format.

9. The method of claim 7, further comprising: receiving, by the in-memory persistent database, an application layer read request to read configuration data stored in the configuration data structure, the read request including the second API key, and transmitting, by the in-memory persistent database, the configuration data stored in the configuration data structure indexed by the second API key.

10. The method of claim 7, further comprising: updating, by the in-memory persistent database, the configuration data with data from the at least one data pipeline data structure indexed by the first API key.

11. A system for managing data at a gateway device receiving sensor data, comprising:
a plurality of drivers executing on one or more servers, each of the plurality of drivers configured to:
receive sensor data over a different communication protocol;
an in-memory persistent database executing on one or more servers, wherein the in-memory persistent database is configured to:
provide a common API to the plurality of drivers,
receive via the common API a data store request from at least one driver from the plurality of drivers, the data request including a first API key unique to a first set of sensors,
store data received from the at least one driver in at least one data pipeline data structure, the at least one data pipeline data structure indexed by the first API key;
receive from a data sender application via the common API, a data pull request including the first API key, and
provide data stored in the data pipeline data structure indexed by the first API key to the data sender application; and
a data sender application running on the one or more servers, the data sender application configured to:
transmit to a remote server the data stored in the data pipeline structure provided by the in-memory persistent database.

12. The system of claim 11, wherein the at least one data pipeline data structure includes a data pipeline, and wherein the in-memory persistent database is configured to:
store sensor data received from the at least one driver in the data pipeline.

13. The system of claim 11, wherein the at least one data pipeline data structure includes an events pipeline, and wherein the in-memory persistent database is configured to:
store sensor events data received from the at least one driver in the events pipeline.

14. The system of claim 11, wherein the at least one data pipeline data structure includes a conditions pipeline, and wherein the in-memory persistent database is configured to:
store sensor conditions data received from the at least one driver in the conditions pipeline.

15. The system of claim 11, wherein the in-memory persistent database is configured to:
store data in the at least one data pipeline data structure in a sorted set based on time stamps associated with the data.

16. The system of claim 11, wherein the in-memory persistent database is configured to:
store on demand data in the at least one data pipeline data structure in a non-volatile disc.

17. The system of claim 11, wherein the in-memory persistent database is configured to:
receive an application layer store request to store configuration data, the request including a second API key unique to the first set of sensors and configuration data, and
store the configuration data in a configuration data structure indexed by the second API key.

18. The system of claim 17, wherein the configuration data is in JSON format, and wherein the in-memory persistent database is configured to store the configuration data in the received JSON format.

19. The system of claim 17, wherein the in-memory persistent database is configured to:
receive an application layer read request to read configuration data stored in the configuration data structure, the read request including the second API key, and
transmit the configuration data stored in the configuration data structure indexed by the second API key.

20. The system of claim 17, wherein the in-memory persistent database is configured to:
update the configuration data with data from the at least one data pipeline data structure indexed by the first API key.
